(19) United States
(12) Patent Application Publication
(10) Pub. No.: US 2010/0039754 A1
(43) Pub. Date: Feb. 18, 2010

(54) SLIDING STRUCTURE FOR USE IN ELECTRONIC DEVICE

(75) Inventor: CHING-HUA CHENG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: CHI MEI COMMUNICATION SYSTEMS, INC., Tu-Cheng City (TW)

(21) Appl. No.: 12/269,131

(22) Filed: Nov. 12, 2008

(30) Foreign Application Priority Data
Aug. 13, 2008 (CN) 200810303749.8

(51) Int. Cl. H05K 5/00

(52) U.S. Cl. 361/679.01

(57) ABSTRACT

A sliding structure includes a stator, a slider, and a plane spring. The slider is slidably disposed on the stator. The plane spring is interposed between the stator and the slider. The plane spring includes two spiral portions which curl into two inverse directions towards two center portions. The two center portions of the plane spring are respectively fixed to the stator and the slider so that the plane spring is capable of pushing the slider to slide to one of two maintaining positions in a latter half of a slide operation between the two maintaining positions.

### BACKGROUND

1. Technical Field

The present disclosure relates to a sliding structure for use in an electronic device.

2. Description of the Related Art

Current sliding structures used in portable electronic devices such as mobile phones typically include a keypad segment on which a keypad is installed and a display segment on which a display is installed. The display segment is slidably coupled with the keypad segment via tracks and can be pushed to slide past the keypad segment to an opened position such that the keypad is exposed or a closed position such that the keypad is covered. The shortcoming of utilizing such a sliding structure is, in operation, in order to open or close the keypad, a user need to push the display segment over the whole slide operation, which is inconvenient.

Therefore, it is desirable to provide a sliding structure which can overcome the above-mentioned problem.

### BRIEF DESCRIPTION OF THE DRAWINGS

FIG. 1 is a schematic, isometric, exploded view of a sliding structure including a slider and an S-shaped torsion spring, according to an exemplary embodiment.

FIG. 2 is a schematic, isometric, assembled view of the sliding structure of FIG. 1, where the slider is in a closed position.

FIG. 3 is a schematic, isometric, assembled view of the sliding structure of FIG. 1, where the slider is in an opened position.

FIGS. 4-7 are graphs respectively showing four states of the S-shaped torsion spring of FIG. 1.

FIG. 8 is a graph showing state-force relationship of the S-shaped torsion spring of FIG. 1.

### DETAILED DESCRIPTION

Embodiments of the present sliding structure will now be described in detail with references to the accompanying drawings.

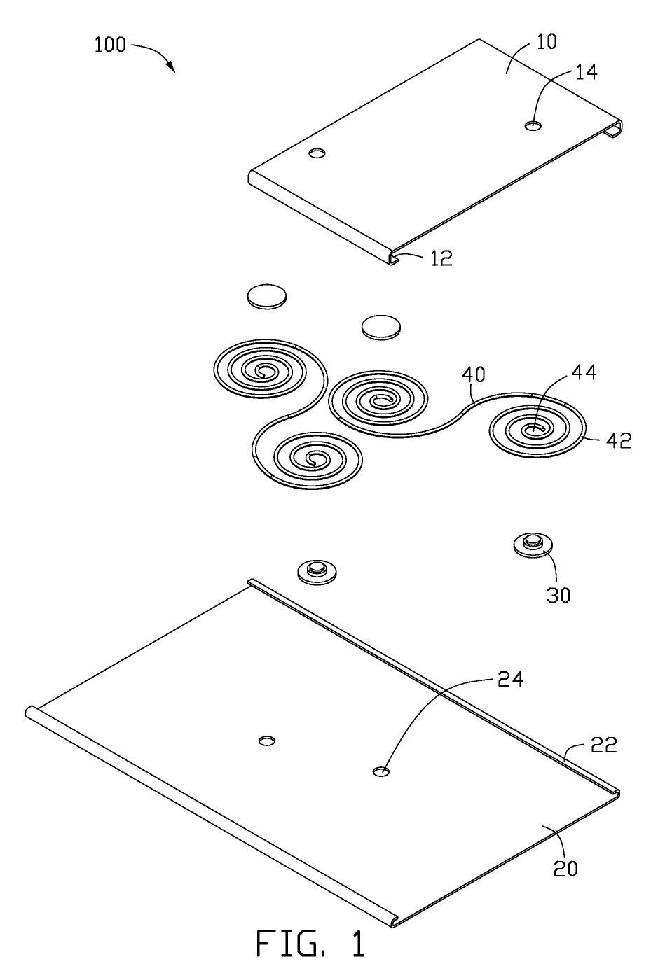

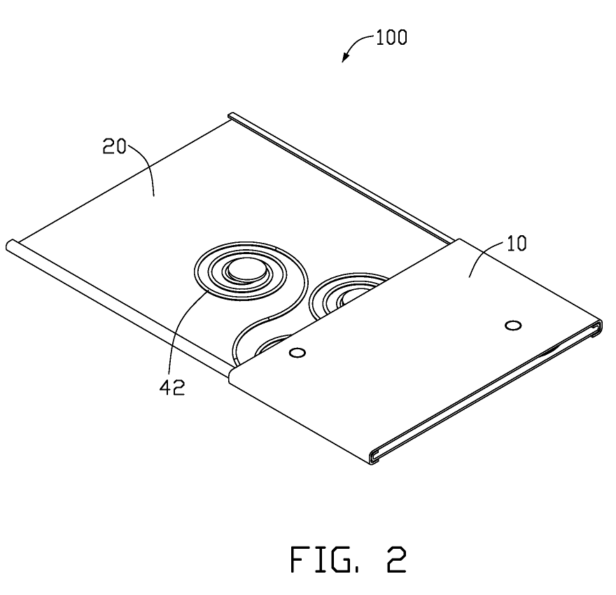

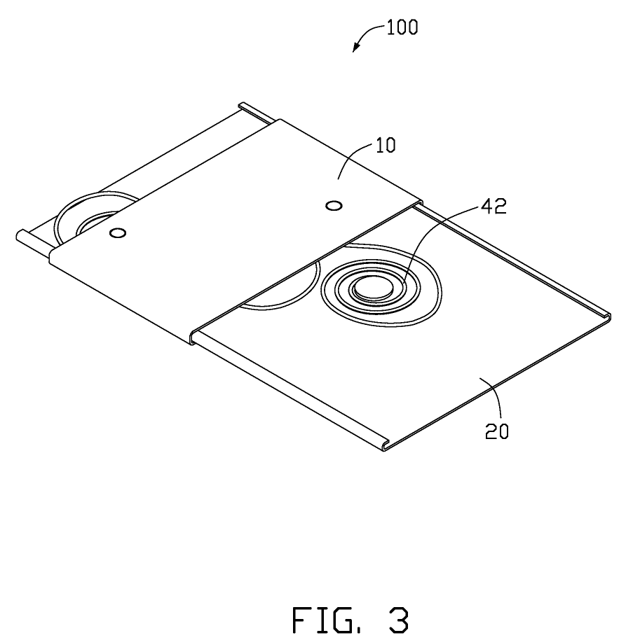

Referring to FIG. 1, a sliding structure 100, according to an exemplary embodiment, includes a slider 10, a stator 20, four fasteners 30, and two S-shaped torsion springs 40. The stator 20 includes two tracks 22. The slider 10 includes two track-receiving portions 12. The slider 10 is disposed on the stator 20 with the two tracks 22 of the stator 20 correspondingly received by the two track-receiving portions 12 of the slider 10. The S-shaped torsion springs 40 are planar, and interposed between the slider 10 and the stator 20. Each of the S-shaped torsion springs 40 includes two spiral portions 42. The two spiral portions 42 curls into two different directions towards two center portions 44 correspondingly. The center portions 44 are fixed to the slider 10 and the stator 20 respectively via the fasteners 30 so that the S-shaped torsion springs 40 are capable of pushing the slider 10 to slide to a closed position (see FIG. 2) or an opened position (see FIG. 3) in a latter half of a slide operation between the closed position and the opened position.

Schematically, the stator 20 of this embodiment is a strip-shaped plate having two parallel edges thereof rolled upwards and inwards to form the two tracks 22. The slider 10 is also a strip-shaped plate having two parallel edges thereof rolled downwards and inwards to form the track-receiving portions 12. Thereby, the slider 10 can be slidably disposed on the stator 20 via the cooperation of the tracks 22 and the track-receiving portions 12. In practice, the slider 10 and the stator 20 may respectively define a chamber and may further accommodate various electronic components. Furthermore, a keypad may be formed on the area of the stator 20 covered by the slider 10 when the slider 10 is in the closed position (see FIG. 2) and a display may be installed on the surface of the slider 10 facing away the stator 20, to form a keypad segment and a display segment.

The slider 10 and the stator 20 are not limited to this embodiment and can take other forms. For example, in other alternative embodiments, the tracks are formed on the slider and the track-receiving portions are defined in the stator.

In this embodiment, the fasteners 30 are short screws. The slider 10 and the stator 20 respectively define two corresponding threaded holes 14, 24 thereon. Thereby, the fasteners 30 can fasten the center portions 44 of each S-shaped torsion spring 40 to the slider 10, by inserting the fastener 30 through one center portion 44 and into the threaded hole 14, and the stator 20, by inserting the fastener 30 through the other center portion 44 into the threaded hole 24. However, the fasteners 30 are not limited to this embodiment and can take other forms.

In this embodiment, the S-shaped torsion springs 40 can be formed by steel wire which is made from SUS201 stainless steel. The diameter of the steel wire is about 0.45 millimeters (mm). However, it should be noted that the material of the S-shaped torsion springs 40 are not limited to this embodiment. For example, in other alternative embodiments, the S-shaped torsion spring 40 also can be formed by, e.g., elastic plastic wire.

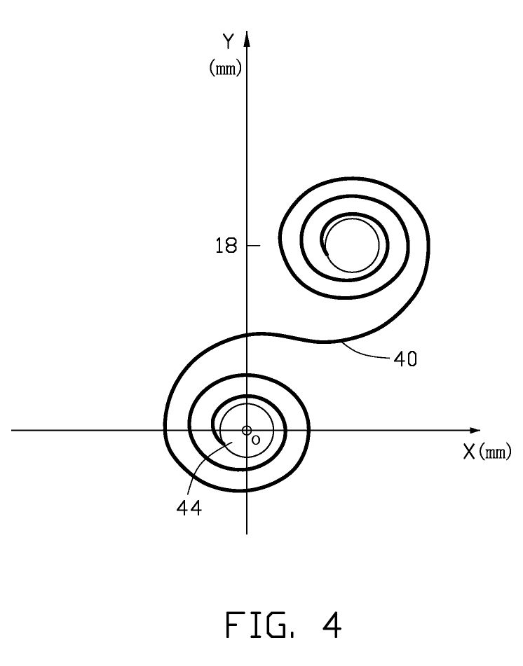

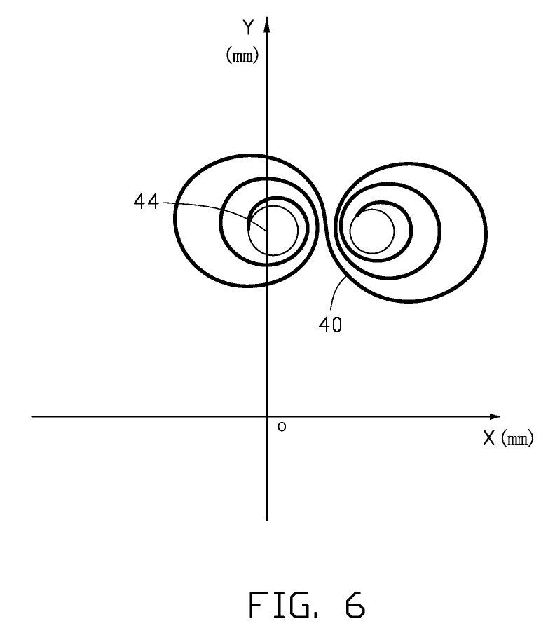

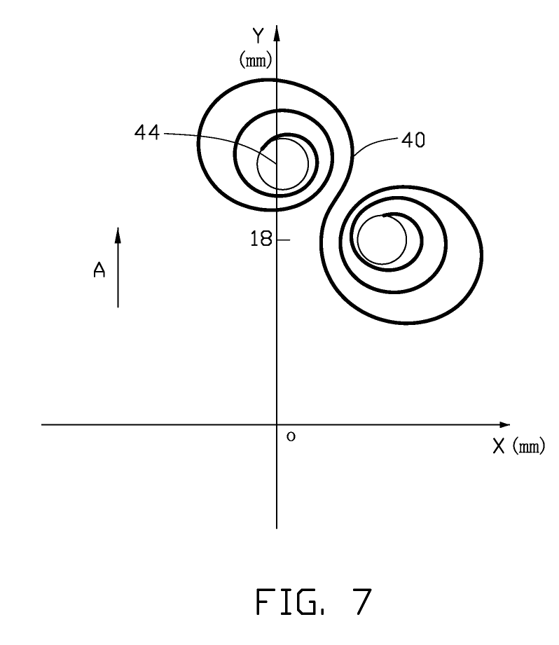

In order to give a better understanding of sliding operation of the sliding structure 100, a description of how the S-shaped torsion spring 40 works in a sliding operation is detailedly described below with the accompany FIGS. 4-8.

Referring to FIG. 2, firstly, the two center portions 44 of the S-shaped torsion spring are fixed to the slider 10 and the stator 20 so that: (1) when the slider 10 is in the closed position, the S-shaped torsion spring 40 is in a compressed state or a normal state; and (2) the two spiral portions 42 can move pass each other in the sliding operation. Thereby, in view of (1), the slider 10 can remain in the closed position without external force. In view of (2), the two center portion can move past each other to complete the slide operation.

Referring to FIG. 4, in order to show movements/deformations of the S-shaped torsion springs 40, an X-Y coordinate is provided. One of the S-shaped torsion springs 40 of FIG. 2 is mapped to the coordinate OXY, where one of the two center portions 44 moves during the entire slide operation (hereinafter “moving center”) and the other is stationary. Initially, the slider 10 is in the closed state, and its Y-axis value is zero millimeters (mm) (see FIG. 4)

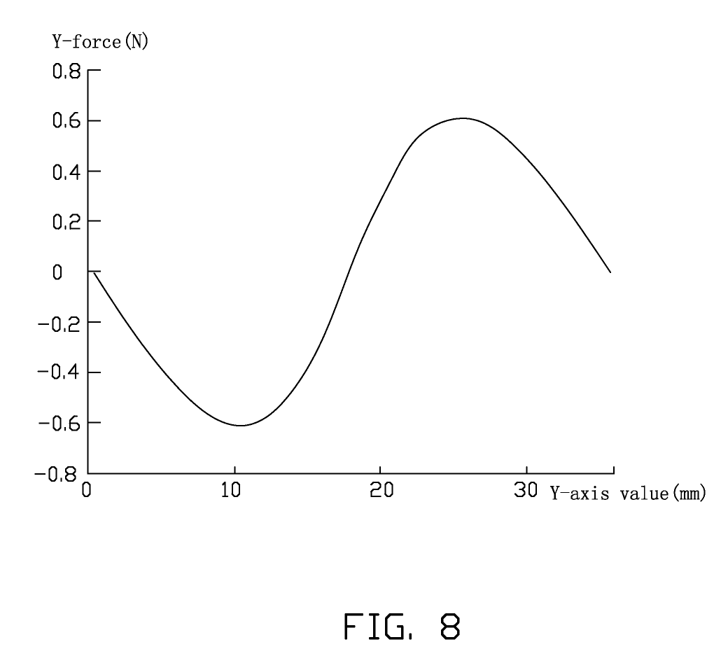

In this embodiment, when the slider is in the closed state, the S-shaped torsion spring 40 is in the natural state, it exerts no force on the slider 10 (see FIG. 8).

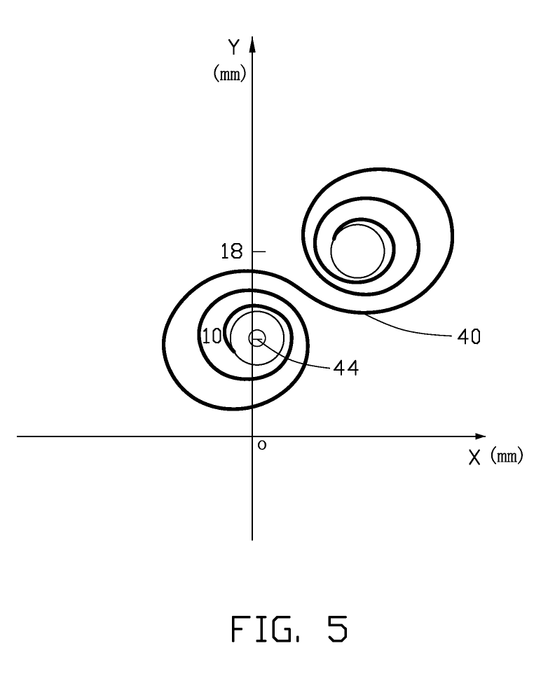

Referring to FIGS. 5-7, when an external force is exerted on the slider 10 to move the slider 10 to slide toward the positive Y-axis. A component of the elastic force stored by the S-shaped torsion spring 40 parallel to the Y-axis (hereinafter “the Y-force”) increases until a critical value, e.g., about −0.6 Newton (N) (see FIG. 8). After reaching the critical value, the Y-force decreases until 0 Newton (N), where the connection line of the two center portions 44 is aligned perpendicular to the Y-axis (see FIG. 8). Then, the Y-force overturns its direction. That is, the Y-force changes its direction to the sliding direction of the slider 10. Therefore, the S-shaped torsion spring 40 becomes automatically pushing the slider 10 to finish the spare sliding operation without assist of the external force.

More S-shaped torsion springs can be employed to increase elastic force exerted on the slider 10. Also, in order to reduce cost, only one S-shaped torsion spring can be employed in the sliding structure 100.

The sliding structure 100 is semi-automated by the S-shaped torsion springs 40. Slide operation becomes more inconvenient, as compared with current sliding structure.

It will be understood that the above particular embodiments and methods are shown and described by way of illustration only. The principles and the features of the present invention may be employed in various and numerous embodiments thereof without departing from the scope of the invention as claimed. The above-described embodiments illustrate the scope of the invention but do not restrict the scope of the invention.

What is claimed is:

1. A sliding structure for use in an electronic device, comprising:
a stator forming two tracks thereon;
a slider defining two track-receiving portions therein and disposed on the stator so that the two tracks are slidably received in the track-receiving portions;
two fasteners;
a plane spring interposed between the stator and the slider and comprising two spiral portions, the spiral portions curling into two inverse directions towards two center portions, the two center portions being respectively fixed to the stator and the slider via the two fasteners so that the plane spring is capable of pushing the slider to slide to one of two maintaining positions in a latter half of a slide operation between the two maintaining positions.

2. The sliding structure as claimed in claim 1, wherein each of the fasteners includes a short screw, the slider and the stator respectively defining a threaded hole, the center portions of the plane spring being fixed to the slider and the stator by inserting the short screws through the center portions of the plane spring and screwing them into the threaded holes.

3. The sliding structure as claimed in claim 1, wherein the S-shaped torsion springs is formed by steel wire.

4. The sliding structure as claimed in claim 3, wherein the steel wire is made from SUS201 stainless steel.

5. The sliding structure as claimed in claim 3, wherein the diameter of the steel wire is about 0.45 mm.

6. A sliding structure comprising:
a stator;
a slider slidably disposed on the stator; and
a plane spring interposed between the stator and the slider and comprising two spiral portions curling into two inverse direction towards two center portions which are respectively fixed to the stator and the slider so that that the plane spring is capable of pushing the slider to slide to one of two maintaining positions in a latter half of a slide operation between the two maintaining positions.

7. The sliding structure as claimed in claim 6, wherein the slider forms two tracks, the stator forming two track-receiving portion corresponding to the two tracks, the slider being slidably disposed on the stator with the tracks correspondingly received by the track-receiving portions.

8. The sliding structure as claimed in claim 6, wherein the S-shaped torsion springs is formed by steel wire.

9. The sliding structure as claimed in claim 8, wherein the steel wire is made from SUS201 stainless steel.

10. The sliding structure as claimed in claim 8, wherein the diameter of the steel wire is about 0.45 mm.
